(19) United States
(12) Patent Application Publication
(10) Pub. No.: US 2006/0067453 A1
(43) Pub. Date: Mar. 30, 2006

(54) Timing circuit for data packet receiver

(75) Inventor: Marcus Duelk, Atlantic Highlands, NJ (US)

Correspondence Address: LUCENT TECHNOLOGIES INC.;DOCKET ADMINISTRATOR, 101 CRAWFORDS CORNER ROAD - ROOM 3J-219, HOLMDEL, NJ, 07733, US

(73) Assignee: Lucent Technologies Inc., Murray Hill, NJ (US)

(21) Appl. No.: 10/955,568

(22) Filed: Sep. 30, 2004

(51) Int. Cl. H03D 3/24

(52) U.S. Cl. 375/376

(57) ABSTRACT

A timing circuit for a receiver adapted for receiving data packet transmissions, each packet having a particular data frequency, the timing circuit comprising: (a) a clock generating circuit for generating a clock signal derived from a local reference clock signal and not from received data packets; and (b) a phase shifter circuit for synchronizing the phase of the clock signal to that of the particular data frequency

### FIELD OF INVENTION

The present invention relates generally to a timing circuit for a receiver, and, more specifically, to a timing circuit for a receiver especially adapted for receiving separated or bursts of data packets.

### BACKGROUND

In the data communication field, applications have arisen recently requiring information to be transmitted as separated data packets or bursts of data packets, rather than as a continuous and synchronous stream of data. Examples of such applications include Ethernet, Passive Optical Networks (PONs) or packet routing and switching. These new applications present challenges over traditional continuous and synchronous transmissions as described below.

By way of background, the various types of data transmission are illustrated in FIG. 2. Scheme (A) illustrates a conventional transmission of data between a transmitter and a receiver in a continuous and synchronous mode over dedicated point-to-point connections at a fixed clock frequency. Such a scheme is used, for example, in Synchronous Optical Networks (SONET). In such networks, all transmitters and receivers are synchronized to run at the same clock frequency, which therefore means that data (e.g. digital bits of 1s and 0s) are transmitted and received at the same rate.

A continuous and synchronous transmission requires that the receiver synchronize its internal clock not only to match the frequency to the incoming data, but also to adjust the clock phase delay so that the incoming data are properly sampled and received without errors. In other words, the receiver must recover both the clock frequency and clock phase of the incoming data (herein referred to collectively as “clock recovery”) before data can be received. Since data are being transmitted continuously in this mode, clock recovery is also performed continuously. Thus, only adjustments for slight variances in the frequency and phase are typically needed during clock recovery.

Clock recovery in a continuous mode does require, however, that the stream of data changes over time. That is, the period of time during which the information content does not change in a continuous mode transmission is limited to a certain maximum. In a binary coding scheme, this corresponds to a maximum number of consecutive bits of 1 s or 0s, which is typically on the order of tens to hundreds of bits. This limit may be due to the particular architecture of clock synchronization at the transmitter or receiver, or to constraints in data monitoring features which would detect a “loss of signal” if the period of unchanging information content exceeds a certain maximum.

In data packet transmission mode, as shown in scheme (B) of FIG. 2, data packets are transmitted in dedicated time slots. The packets may originate from different transmitters which establish different point-to-point connections with a particular receiver. The duration of these point-to-point connections can be very short—as short as the length of a data packet. For example, an TCP/IP packet can be as short as 320 bits (40 bytes). After one data packet is transmitted, a new point-to-point connection between the receiver and a different transmitter may be established. All transmitters are sending data at essentially the same data rate (i.e. same clock frequency).

As in the case of synchronous or continuous data transmissions, the receiver must perform clock recovery in scheme (B) before the data can be received. This means that the receiver must adjust mainly the clock phase delay for each incoming data packet since the clock frequency of all packets is the same. Furthermore, since the data packets are received regularly in dedicated time slots, the clock phase will be known to a certain degree, requiring only slight adjustment and thereby minimizing overhead.

Like scheme (A), the period of time during which the information content does not change is limited in scheme (B). This limitation is not typically a problem from data packets themselves since, by their nature, they are short, although it is important with respect to the “idle time” between data packets during which no information is exchanged. The number of consecutive identical bits during the idle time can be hundred to thousands bits. Nevertheless, clock recovery is manageable in this scheme since the data packets are transmitted in dedicated time slots, and, thus, their timing is already known within certain limits.

In burst mode transmission, as shown in scheme (C) of FIG. 2, data packets are received in an irregular fashion so that the idle time between data transmissions exceeds one or several packet lengths. It might be even that the time during which data are sent and received is very small compared to the idle time during which no data are sent or received. Similar to scheme (B), data packets may be transmitted by different transmitters, which all operate at the same clock frequency. However, unlike packet transmissions in scheme (B), data transmitted in burst mode are not within dedicated time slots and thus more effort is required to re-synchronize the data with the receiver as discussed below.

Referring to FIG. 3, for packet and burst transmission systems, a re-synchronization (re-sync) time 31 at the beginning of each packet 30 is needed before the data payload 32 can be received correctly. The required re-sync time depends on the transmission format (e.g. length of idle time) and also on the architecture of the clock recovery circuit at the receiver. In this re-sync period the receiver timing circuit detects (recovers) the clock frequency and phase delay of the incoming data and adjusts local frequency oscillators so that data processing can be performed without inducing bit errors. Typically, the longer the idle time, the longer is the required re-sync time which increases the overhead for burst transmission. This is due to inherent frequency drifts which is problematic in phase-locked loop circuits typically used in re-sync circuitry.

The most common timing circuit architecture for receivers is based on a phase-locked loop (PLL). A PLL is a mechanism which causes a particular system to track with another one. More precisely, a PLL is a circuit for synchronizing an output clock signal, typically that of an oscillator, with an input signal both in frequency and in phase. In common receiver architectures, the input signal is the data signal and the PLL is combined with a re-timing circuit in which the incoming data are sampled with the clock of the internal oscillator. This way, the incoming data are “re-timed” with the local clock of the internal oscillator.

An example of a typical receiver PPL architecture 40 with integrated clock-data recovery (CDR) and demultiplexing (demux) stage is shown in FIG. 4. The key elements of a PLL are a phase detector (PD) 41, a loop filter 42 and a feedback to a voltage-controlled oscillator (VCO) 43. The phase detector can be analog or digital, although the phase detector depicted in FIG. 4 is digital. In this embodiment, the digital phase detector comprises latches for sampling the received data 44 based on the timing of an internal clock. The digital phase detector 41 generates a timing signal 52 and a digital output signal 45a with logical states “up” and “down.” This digital signal 45a is converted into an analog signal 45b in an analog-to-digital converter 50 before it is fed back to the VCO 43. If an analog phase detector is used rather than a digital phase detector, the frequency and phase of the internal VCO are compared with a clock tone generated from the received serial data. The output of the analog phase detector is a time-varying voltage signal which is integrated in the loop filter of the PLL and fed back to adjust the voltage of the VCO.

The feedback path from the phase detector 41 to the VCO 43 typically comprises a proportional (P) path 47 and an integrator (I) path 48. The P-path 47 is used to perform immediate phase adjustments between received data and internal clock. In parallel, the proportional feedback signal 45b is sent through the low-pass filter (LPF) 42. The integration in this I-path takes care of frequency deviations between received data and internal VCO as long as the deviations lie within a specified frequency window (typically tens of ppm). Otherwise, a frequency-window detector (FWD) 46 will overwrite and disable the PLL and adjusts coarsely the frequency of the VCO by means of a low-frequency reference clock 49. The frequency of the reference clock is typically on the order of hundred to thousand times smaller than the actual data rate. For SONET transmission systems, this reference clock is typically an 8 kHz clock of a certain Stratum accuracy level or a higher frequency that is derived from this time reference. It is therefore often necessary to adjust the clock frequency by means of dividers/multipliers.

The phase detector 41 in this embodiment is integrated with a first 1:2 demux stage. The phase detector comprises latches which sample the input data at bit rate BR with a half-rate clock, performing simultaneously a 1:2 demultiplexing. Additional demultiplexing stages 53 may follow to lower the bit rate of the output signals so that they can be handled in a deframer chip 54.

The PLL architecture is powerful in the sense that a clean (low phase noise and timing jitter) clock tone can be extracted from the incoming data over a wide frequency range. The locking range of the PLL is typically several MHz so that like frequency deviations between transmitter and receiver can be handled. By changing the reference clock the receiver may actually work over a wide range of several GHz.

Although the conventional PLL architecture is well suited for data having little or no idle time between data packets, they are not well suited for bursts of data packets. For long sequences of identical bits or when no data are received the proportional output signal from the phase detector typically vanishes. The reason for this is that timing information can be only extracted in the transitions of the bits. When no timing information is received, the drive signal in the P-path 47 becomes zero and the signal in the I-path 48 decays with the time characteristics of the loop filter 42. The changing signals in the P-path 47 and I-path 48 of the PLL 40 will drive the VCO 43 to a different clock frequency. Depending on the length of the idle time, the VCO 43 may exceed the limits of the frequency window which will disable the PLL and cause the internal clock in the digital phase detector 41 to be set according to the reference clock 49, as discussed above. The detrimental affects of idle time between data packets may be mitigated by increasing the bandwidth of the P-path to perform fast phase adjustments and by decreasing the bandwidth of the I-path so that the VCO holds its frequency during the idle time in which no data are received. Although this may help, there are several constraints that limit the maximum idle time that can be tolerated. For example, current leakage and other parasitic effects in the electronic circuitry of the receiver limit typically the maximum integration of the I-path to a certain amount. Thus, longer idle times will lead to higher frequency drifts of PLLs which will result in longer times needed for synchronization and, hence, more overhead. Consequently, PLLs may be accepted to a certain extent for packet transmission where packet reception might be guaranteed for each time slot, but PLLs cannot be used for true burst-mode reception with potentially very long idle times.

Therefore there is a need for a synchronization architecture for transmission of data bursts which is tolerant to undefined idle times between the bursts. The present invention fulfills this need among others.

### SUMMARY OF INVENTION

The present invention involves the recognition that acquiring the frequency of the data rate by monitoring the data received is not necessary for data packets, particularly burst data packet transmissions. Not only is it not necessary, but it is also potentially detrimental as described above with respect to frequency drift during idle periods. Specifically, the feedback to the frequency oscillator employed in conventional phase-locked loop (PPL) circuitry results in frequency drifts during idle times, necessitating longer re-sync times and, thus, increasing overhead.

The present invention avoids this problem by providing a timing circuit architecture for a receiver which does not acquire the data rate frequency by monitoring the incoming data, but rather establishes a clock signal using a local reference clock which is fixed and independent of the data packets. The reference clock is preferably the same reference clock used by the transmitter in generating the data so the frequency of the data rate is established in the same fashion at both the receiver and the transmitter. In other words, the receiver uses a high-precision PLL to generate a local clock at the required data rate frequency with low timing jitter and phase noise, similar to the transmitter.

The remaining task before the incoming data can be received is therefore to adjust the phase of the local clock with that of the incoming data. As discussed above, phase adjustment must be performed rather quickly to minimize re-sync times. This is performed preferably using a broad-bandwidth delay-locked loop (DLL). Like a PPL, a DDL uses a phase detector which outputs a control signal if a phase difference between local clock and incoming data is detected. The control signal is fed back to a high-speed phase shifter which performs the required phase adjustment. Since the feedback from the phase detector is used only to adjust the phase delay and not the frequency of the local clock, frequency drift during idle times cannot occur.

By decoupling frequency and phase acquisition, the receiver of the present invention is well suited to handle long idle times in which no data are received. While standard PLLs suffer from frequency drifts during long idle times resulting in prolonged synchronization times or synchronization failures, the PLL-DLL receiver concept of the present invention eliminates frequency drifts during idle times so that the synchronization time of the receiver is solely determined by the loop bandwidth of the DLL and is therefore more predictable. Furthermore, since the same PLL for generating a high-frequency clock out of a low-frequency reference clock is used on the transmitter and receiver side, a burst-mode transceiver chip can be implemented with only one PLL that is shared for transmit and receive side. This may minimize power consumption, chip size and complexity.

Accordingly, one aspect of the present invention is a timing circuit for a receiver adapted for receiving data packets using decoupled frequency and phase synchronization circuitry. In a preferred embodiment, the timing circuit comprises: (a) a clock generating circuit for generating a clock signal derived from a local reference clock signal and not from received data packets; and (b) a phase shifter circuit for synchronizing the phase of the clock signal to that of the received data. Preferably, the clock generating circuit is a narrow-bandwidth phase-locked loop (PLL), while the phase shifter circuit is a broad-bandwidth delay-locked loop (DLL).

Another aspect of the present invention is a receiver adapted for receiving burst data packets. In a preferred embodiment, the receiver comprises a timing circuit comprising at least (a) a clock generating circuit for generating a clock signal derived from a local reference clock signal and not from received data packets; and (b) a phase shifter circuit for synchronizing the phase of the clock signal to that of the received data. One embodiment involves packaging the receiver with a transmitter in a transceiver. In such an embodiment, it is preferable for the clock generating circuit to be common to both the receiver and the transmitter such that the same clock signal is used to transmit and receive data.

Yet another aspect of the present invention is a re-synchronization process for receiving data packets by establishing the frequency of the data rate independent of data packets received. In a preferred embodiment, the process comprises: (a) generating a clock signal based on a local reference clock signal and not by sampling received data packets; and (b) shifting the phase position of the clock signal to synchronize the phase of the clock signal with that of the particular data frequency by sampling the data packets. The process of the present invention is particularly well suited for handling data packets in which the idle time between packets is greater than the length of one or more of the packets.

### BRIEF DESCRIPTIONS OF DRAWINGS

FIG. 1 shows the architectural scheme of a timing circuit of the present invention having a phase-locked loop to establish frequency of the data rate and a delay-locked loop to establish the phase position of the data rate of the incoming signals.

FIG. 2 shows the different modes in which data packets may be transmitted.

FIG. 3 shows schematically the re-synchronization time for each data packet before the payload of the packet/burst can be detected correctly.

FIG. 4 shows a timing circuit architecture for synchronous data reception using a PLL with a digital phase detector for clock-data recovery and demultiplexing.

### DETAILED DESCRIPTION

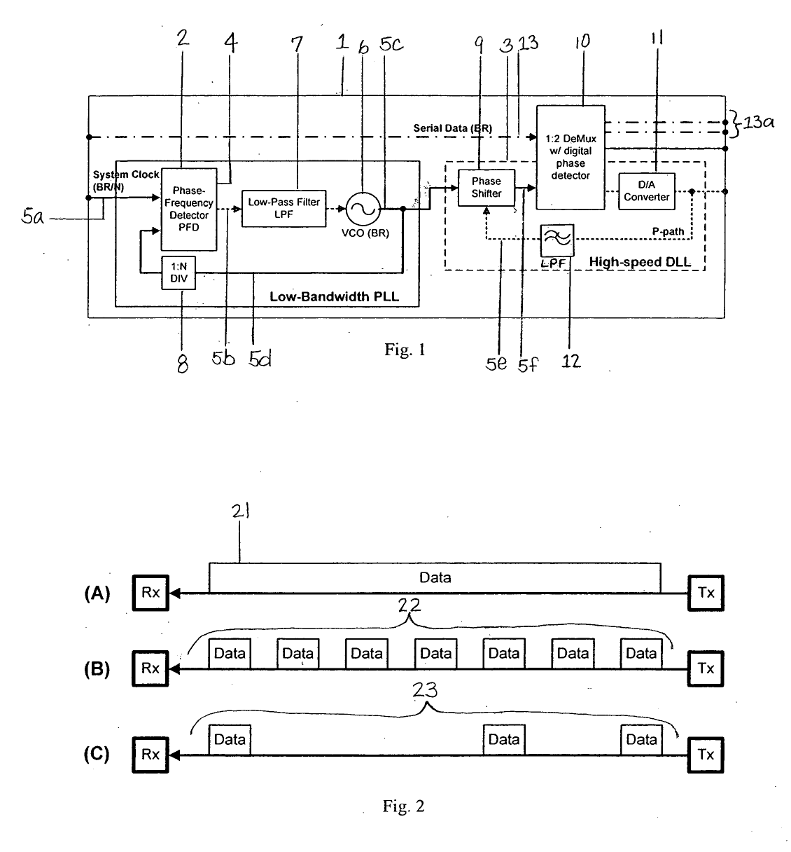

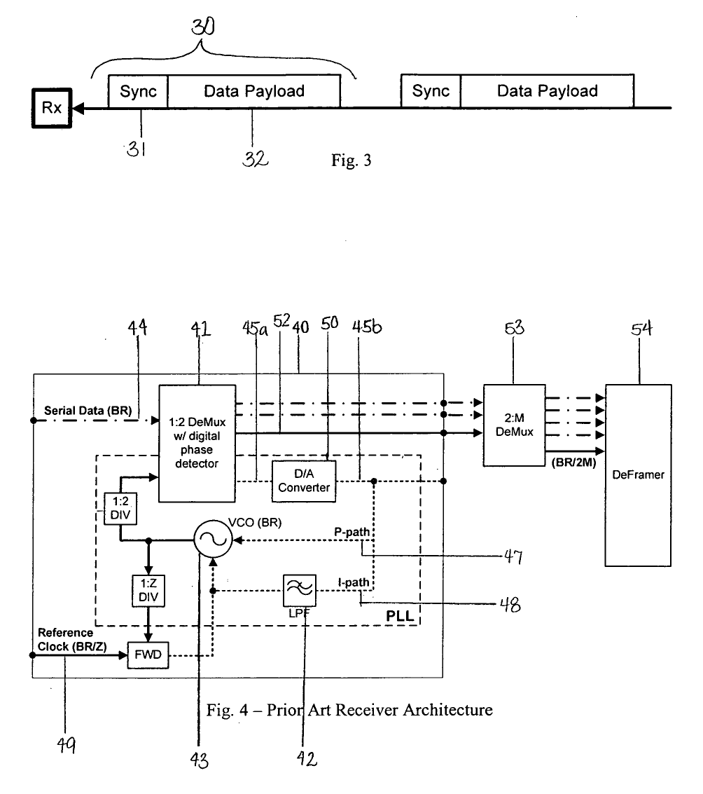

The present invention provides a timing circuit architecture for transmission systems in which packets or bursts of data are transmitted at a known and fixed clock frequency. Referring to FIG. 1, a schematic of a preferred embodiment of a data packet receiver 1 of the present invention is show. The receiver 1 is suitable for receiving data packet transmissions having sporadic or burst data packets. Each data packet comprises data having a particular data frequency. The receiver 1 comprises (1) a clock generating circuit 2 for generating a clock signal which is derived from a fixed reference clock signal and not from received data packets; and (2) a phase shifter circuit 3 for synchronizing the phase of the clock signal to that of the received data packet transmissions by sampling the data packets. These two circuits are discussed below in greater detail.

The frequency generation circuit 2 functions to establish the frequency of the data rate without sampling the received data. Preferably, the frequency generation circuit 2 comprises a phase-locked loop (PLL) circuit having a narrow bandwidth as shown in FIG. 1. The narrowband PLL generates a low-jitter clock at the full data rate (or at half the data rate, depending on the phase detector design) based on a low-frequency timing reference. For example, this circuitry may generate a 9.95328 GHz clock out of a 19.44 MHz reference clock signal, i.e. the generated clock is a factor N=512 higher than the reference clock.

As shown, the frequency generation circuit 2 comprises a phase-frequency detector (PFD) 4, a loop filter (LPF) 7, a voltage-controlled oscillator (VCO) 6, and a frequency divider 8. The PFD 4 compares the frequency (and phase) of the reference clock 5a with the frequency of a clock signal 5d derived from the data rate clock signal 5c output of the VCO 6, typically by dividing it down by a factor N in the frequency divider 8. The PFD outputs a control signal 5b which is sent through a loop filter 7 to the VCO 6 to adjust the frequency.

In this clock generating circuit, the PFD 2 is used instead of a phase detector (PD) because the low-bandwidth PLL does not need to track the phase, but just the frequency of the local reference clock signal 5a. Standard phase detectors, whether digital or analog, are quite capable of tracking phase difference, but tend to be unsuitable for tracking large frequency differences. PFDs are well-known building blocks of PLLs. The bandwidth and filter characteristics of the PLL are determined by the loop filter. More precisely, the bandwidth characteristics of the PLL are determined by the time constants of an I-path and an P-path, and the lowpass filter characteristics of other building blocks of the PLL, for instance of the VCO. The circuitry of generating a high-frequency and high-quality clock by means of a low-frequency reference is known to one skilled in the art.

The local reference clock signal is preferably the clock (or an integer multiple of it) upon which the entire communication network operates. For example, in the SONET protocol the common clock is 8 kHz which corresponds to the SONET frame length of 125 μs. Low-frequency reference clock signals for transmitters and receivers are, for example, at a typical frequency of 19.44 MHz, which is 2430 times the fundamental frequency of 8 kHz. Such reference clock signals are well known to one skilled in the art.

The PLL design here is preferably identical to the clock generation at the transmitter side which means that the frequency inaccuracy and phase noise of both transmitter and receiver are the same. Furthermore, if the same PLL for generating a high-frequency clock out of a low-frequency reference clock is used on the transmitter and receiver side, a burst-mode transceiver chip can be implemented with only one PLL which is shared for the transmit and receive sides. This may minimize power consumption, chip size and complexity.

Once the clock signal 5c is generated, it is transmitted to the phase shifter circuit 3. The phase shifter circuit functions to sample received data 13 and to match the phase position of the particular frequency of the received data 13 with that of the clock signal 5c generated by the clock generating circuit 2. Preferably, the phase shifter circuit is a wideband DLL as shown in FIG. 1. The high bandwidth of the loop filter of the DLL and of the phase detector allows for fast phase adjustments for received packets.

As shown, the phase shifter circuit 3 preferably comprises an analog phase shifter 9 and a phase detector 10. The phase shifter receives the clock signal 5c from the frequency generation circuit 2 and performs the necessary phase shifting based on feedback 5e from the phase detector 10 to generate a phase-shifted clock signal 5f which is synchronized with the phase position of the data rate of the incoming data. If the phase detector is digital, a D/A converter 11 may be needed to convert the output of the phase detector to analog signal. A low-pass loop filter (LPF) 12 may also be required to optimize the performance.

The phase detector 10 in this embodiment is integrated with a first 1:2 demux stage which is a well known configuration. As such, the phase detector comprises latches which sample the input data 13 at bit rate BR with a half-rate clock, performing simultaneously a 1:2 demultiplexing on the received data 13 to generate two data signals 13a having a low frequency. Additional demultiplexers (not shown) may follow to lower further the bit rate of the data signals so that they can be handled in a deframer chip (not shown).

The phase shifter can be any one of a number of mechanisms which can introduce a time delay or phase change for an input clock signal. Preferably for burst-mode detection, the phase shifter is adapted to adjust the phase on the order of nanoseconds. Furthermore, analog phase shifters are preferred that are able to continuously adjust the phase based on a control parameter, such as a control voltage. Continuous phase adjustment during the reception of a data packet might be required if the transmitter and receiver have slightly different clock frequencies. That is, since clock recovery in the present invention is based on a frequency derived from a fixed source, rather than from the data itself, it tends to off slightly and, thus, must be constantly compensated for by the phase shifter. An example of a suitable phase shifter is varactor diodes which induce a phase shift based on an applied voltage signal. This device is described, for example, in Krafcsik et al., “A Dual-Varactor Analog Phase Shifter Operating at 6 to 18 GHz”, IEEE Transactions on Microwave Theory and Techniques, 1988, vol. 36, no. 12, pp. 1938-1941. Such phase shifters can operate over a wide frequency range and are also capable of quickly adjusting the phase. For example, a varactor-based phase shifter can adjust a GHz clock signal by 360 degrees in response to a feedback signal in less than 20 ns.

Although the phase shifter can quickly adjust for phase changes, its tuning range will likely be limited. For example, a typical analog phase shifter is capable of altering the phase position up to about 360 degrees. Once this point is reached, the phase shifter must be reset to compensate any further for phase offset. The phase shifter typically resets between data packets so that data is not affected.

Given the tuning limitations facing a phase shifter, the timing circuit of the present invention probably cannot be used for continuous data transmission but only for packets with a known maximum length. The reason is that the frequency of the clock at the receiver is not synchronized to the clock frequency of the incoming data and bit slips and bit errors may occur when receiving long data sequences. More specifically, the frequency mismatch Δf between the received data and the clock frequency, f, of the receiver will result in a slow walk-off between data and clock signal. The phase shifter of the DLL will compensate the walk-off up to a certain amount depending on its tuning range as mentioned above. Once the phase shifter has reached its tuning limit and cannot compensate further for walk-offs, a bit slip will occur after n bits, given by n=f/Δf. For example, in a 40 Gb/s burst-mode transceiver in which both receiver and transmitter use the same PLL to generate a clock based on a Stratum 3/3E reference clock with 4.6 ppm accuracy, a frequency mismatch Δf of 185 kHz (f=40.000 GHz) will occur. This will cause a possible bit slip after 217,000 bits (5.4 μs long packet payload) in case the phase shifter is out of range.

Thus, the maximum transmission length of the data packet is dependent upon the tuning range of the phase shifter and upon the frequency inaccuracy between transmitter and receiver. The overall tuning range of the DLL should span at least two bit periods (720 degrees), preferably more. This could be achieved by cascading several phase shifter in sequence. The higher the tuning range of the DLL the more tolerant it is to walk-off due to frequency mismatch Δf between transmitter and receiver. If the DLL is capable of tuning the phase of the clock signal by m bit periods, a bit slip will occur after m·n=m·f/Δf bits.

Higher tuning ranges can be achieved by tuning low-frequency clocks and using a clock multiplier. If a clock multiplier is used, tuning one full bit period at the nth fraction of the bit rate results in a tuning range of N bit periods for the bit rate clock after clock multiplication. For example, if the clock is tuned at ¼th of its value and then multiplied by 4 after tuning by the phase shifter, the tuning range of the phase shifter will increased 4 fold. This can have a profound affect on the maximum length of the data which can be handled by the timing circuit of the present invention.

It should be understood that, although a reset of the phase shifter between data packets may be required to minimize the risk of bit slips due to an out-of-range phase shifter, if the time constant of the DLL is smaller than the minimum idle time between data packets or bursts, the phase shifter will perform an automatic reset since the output signal of the loop filter decays during absence of data. Hence, the DLL and its phase shifter will be in the same initial condition for each arriving packet or burst if the idle time is long enough with respect to the DLL time constant.

Although the timing circuit of the present invention may be limited in the length of data packets it can receive without incurring errors, it is not limited in the idle time between data packets. As mentioned above, the timing circuit is designed specifically for burst mode data packets, although it is suitable for any data packets providing that the length of the packets do not have an accumulated error which exceeds the tuning capacity of the phase shifter as discussed above. The timing circuit of the present invention is therefore suitable for receiving data packets having idle times greater than the average length of the data packets, and can even handle idle times which are a hundred or thousand times more than the average length of the data packet.

The timing circuit of the present invention may be incorporated into well known receiver designs, which may, in turn, be packaged in larger systems or in discrete modules. The timing circuit design may be used for electrical domain transmissions or optical domain transmissions. Given the high-responsive properties of the timing circuit, it is particularly well suited for the higher operating speeds characteristic of optical communication systems. The timing circuit architecture can be realized at very high data rates where conventional burst-mode receiver architectures such as oversampling, gated oscillators, multi-phase clock selectors and others can not be realized because these would require much higher speed of electronics. As mentioned above, since the clock generating circuit of the timing circuit is the same as those typically used in transmitters, synergies can be realized by packing the receiver in a transceiver so the same frequency generation circuit can be used for both the receiver and the transmitter.

What is claimed is:

1. A timing circuit for a receiver adapted for receiving data packet transmissions having a particular data frequency, said timing circuit comprising:
a clock generating circuit for generating a clock signal derived from a local reference clock signal and not from received data packets; and
a phase shifter circuit for synchronizing the phase of said clock signal to that of said particular data frequency.

2. The timing circuit of claim 1, wherein said clock generating circuit is a low-bandwidth phase-locked loop (PPL) circuit.

3. The timing circuit of claim 1, wherein said clock generating circuit comprises a phase-frequency detector (PFD) for receiving said local reference clock signal and outputting an intermediate clock signal, a voltage-controlled oscillator (VCO) for generating said clock signal based on said intermediate clock signal.

4. The timing circuit of claim 3, wherein said intermediate clock signal passes through a low-pass filter before reaching said VCO.

5. The timing circuit of claim 3, wherein said VCO transmits said clock signal to said phase shifter circuitry and to said PFD as a first feedback signal.

6. The timing circuit of claim 3, wherein said first feedback signal is conditioned by a multiplier/divider circuit.

7. The timing circuit of claim 1, wherein said phase shifter circuit comprises a broad-bandwidth delay-locked loop circuit.

8. The timing circuit of claim 7, wherein said phase shifter circuitry comprises a phase shifter which adjusts the phase of the said clock signal received from said clock generating circuit based on a second feedback signal derived from said particular data frequency to output a phase-shifted clock signal.

9. The timing circuit of claim 8, wherein said phase shifter circuit further comprises a phase detector which compares said particular data frequency and said phase-shifted clock signal and outputs said second feedback signal for said phase shifter.

10. The timing circuit of claim 9, wherein said phase shifter circuit further comprises a low-pass filter though which said second feedback signal passes before being received by said phase shifter.

11. The timing circuit of claim 8, wherein said phase detector is digital and said phase shifter circuit further comprises a digital to analog converter for converting said second feedback signal outputted from said phase detector to an analog signal.

12. The timing circuit of claim 8, wherein said phase detector also comprises demultiplexing circuitry.

13. The timing circuit of claim 8, wherein said phase shifter is capable of shifting the phase at least 360 degrees.

14. The timing circuit of claim 1, wherein said phase shifter is analog.

15. The timing circuit of claim 1, wherein said phase shifter is capable of continuously shifting the phase for a given data packet transmission.

16. A receiver adapted for receiving data packet transmissions, each packet having a particular data frequency, said receiver comprising:
a timing circuit comprising at least a clock generating circuit for generating a clock signal derived from a local reference clock signal and not from received data packets; and
a phase shifter circuit for synchronizing the phase of said clock signal to that of said particular data frequency.

17. The receiver of claim 16, wherein said data clock generating circuit and said phase shifter circuit are integrated on a common circuit.

18. The receiver of claim 16, wherein said receiver is part of a transceiver having a transmitter, and said clock signal is used by said transmitter to generate data packets having a particular data frequency.

19. The receiver of claim 16, wherein said receiver is adapted for receiving optical data packets.

20. The receiver of claim 16, wherein said receiver is adapted for receiving electrical data packets.

21. The receiver of claim 16, wherein said receiver packaged in a module.

22. A method of receiving data packets, each data packet having a particular data frequency, said method comprising:
generating a clock signal based on a local reference clock signal and not from said particular data frequency; and
shifting said phase position of said clock signal to synchronize the phase of the clock signal with that of said particular data frequency.

23. The method of claim 22, wherein said data packets are separated by a time greater than the length of a data packet of said data packets.

24. The method of claim 23, wherein said data packets are separated by a time greater than two times the length of a data packet of said data packets.

24. The method of claim 22, wherein said phase position is monitored continuously and shifted as needed to achieve synchronization while receiving a data packet.
